(19) United States
(12) Patent Application Publication
(10) Pub. No.: US 2015/0074489 A1
(43) Pub. Date: Mar. 12, 2015

(54) SEMICONDUCTOR STORAGE DEVICE AND MEMORY SYSTEM

(71) Applicant: KABUSHIKI KAISHA TOSHIBA, Tokyo (JP)

(72) Inventors: Jin KASHIWAGI, Tokyo (JP); Yasuyuki EGUCHI, Kawasaki-Shi (JP)

(21) Appl. No.: 14/203,468

(22) Filed: Mar. 10, 2014

Related U.S. Application Data
(60) Provisional application No. 61/874,851, filed on Sep. 6, 2013.

(51) Int. Cl. G11C 7/10; G06F 11/10

(52) U.S. Cl. CPC G11C 7/10; G06F 11/10
USPC 714/763; 365/189.14

(57) ABSTRACT

A semiconductor storage device according to the present embodiment comprises a memory cell array comprising a plurality of memory cells, the memory cell array including a first region and a second region. An internal controller is configured to perform writing of data to the memory cells or reading of data from the memory cells. An input/output part is configured to receive the data written to the memory cells or to output the data read from the memory cells. A mode controller is configured to operate a first region in a first mode and a second region in a second mode.

### CROSS REFERENCE TO RELATED APPLICATIONS

This application is based upon and claims the benefit of priority from the prior U.S. Provisional Patent Application No. 61/874,851, filed on Sep. 6, 2013, the entire contents of which are incorporated herein by reference.

### FIELD

The embodiments of the present invention relate to a semiconductor storage device and a memory system.

### BACKGROUND

As large-capacity non-volatile memory, MRAM (Magnetic Random Access Memory) has been widely known.

### BRIEF DESCRIPTION OF THE DRAWINGS

FIG. 1 is a block diagram showing an example of a configuration of a system (a memory system) according to a first embodiment;

FIG. 2 is a block diagram showing an example of a configuration of the MRAM chip 1 according to the first embodiment;

FIG. 3 is an explanatory diagram showing an example of a configuration of the single memory cell MC;

FIG. 4 is a block diagram showing the ECC controller ECCCNT, the main controller MCNT, the error correction code part ECC, and the memory cell array MCA;

FIG. 5 is a block diagram showing the ECC controller ECCCNT, the main controller MCNT, the error correction code part ECC, and the memory cell array MCA according to a modification of the first embodiment;

FIG. 6 is a block diagram showing an example of a configuration of the MRAM chip 1 according to a second embodiment;

FIG. 7 is a block diagram showing an example of a configuration of the MRAM chip 1 according to a third embodiment;

FIG. 8 is a block diagram showing an example of a configuration of the MRAM chip 1 according to a combination of the third embodiment with the second embodiment;

FIG. 9 is a block diagram showing an example of a configuration of the MRAM chip 1 according to a fourth embodiment;

FIG. 10 is a block diagram showing an example of a configuration of a system (a memory system) according to a fifth embodiment;

FIG. 11 is a block diagram showing an example of a configuration of a memory system according to the modification of the fifth embodiment; and

FIGS. 12A to 13B are timing charts showing that the designation of the operation of whether to turn on or off the error correction code part ECC is made to the ECC controller ECCCNT in response to the external commands.

### DETAILED DESCRIPTION

Embodiments will now be explained with reference to the accompanying drawings. The present invention is not limited to the embodiments.

A semiconductor storage device according to the present embodiment comprises a memory cell array comprising a plurality of memory cells, the memory cell array including a first region and a second region. An internal controller is configured to perform writing of data to the memory cells or reading of data from the memory cells. An input/output part is configured to receive the data written to the memory cells or to output the data read from the memory cells. A mode controller is configured to operate a first region in a first mode and a second region in a second mode.

Components with substantially the same functionalities and configurations will be referred to with the same reference number and duplicate descriptions will be made only when required. Note that figures are schematic and the relationship between the thickness and the plane dimension of a film and the ratios of the thickness of one layer to another may differ from actual values. Therefore, it should be noted that a specific thickness and dimension should be determined in accordance with the following description. Moreover, it is natural that different figures may contain a component different in dimension and/or ratio.

While an MRAM is described as a semiconductor storage device in each of the following embodiments, the embodiments are also applicable to other nonvolatile memories (an FeRAM, for example).

### First Embodiment

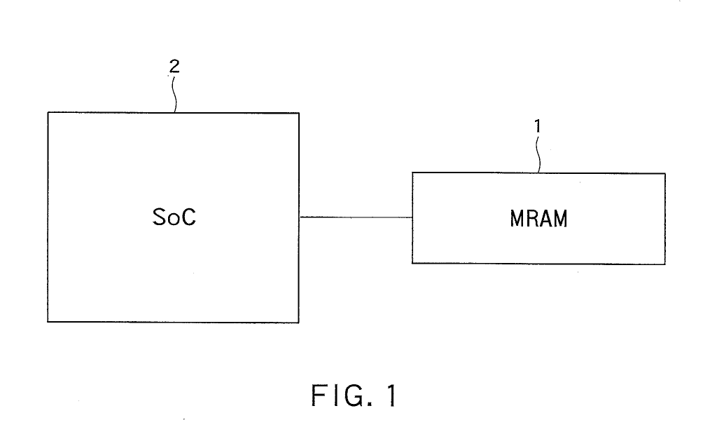

FIG. 1 is a block diagram showing an example of a configuration of a system (a memory system) according to a first embodiment. The system according to the first embodiment includes an MRAM chip 1 and an SoC (System On Chip) 2. For example, the MRAM chip 1 serves as both a work memory and a code storage and is used in place of a DRAM or the DRAM and a NAND. In a case of using the MRAM chip 1 in place of the DRAM and the NAND, the MRAM chip 1 includes therein a work memory region and a code storage region.

While FIG. 1 shows only one MRAM chip 1, the SoC 2 can control a plurality of MRAM chips 1. Furthermore, the SoC 2 and the MRAM chips 1 can be implemented in one package.

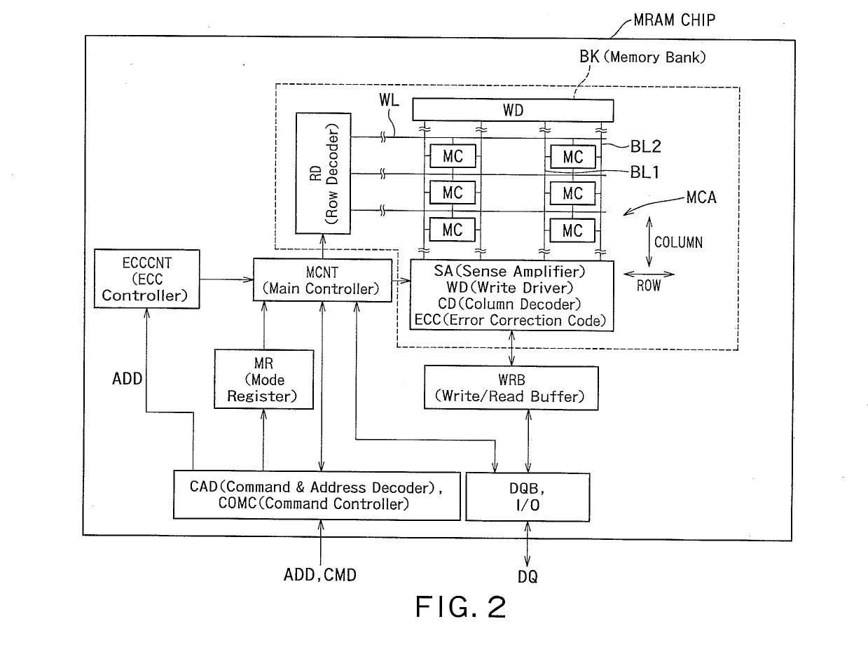

FIG. 2 is a block diagram showing an example of a configuration of the MRAM chip 1 according to the first embodiment. The MRAM chip 1 according to the first embodiment includes a memory bank BK (hereinafter, also simply “bank BK”), a main controller MCNT, a command and address decoder CAD, a command controller COMC, a data buffer DQB, an input/output part I/O, a mode register MR, an ECC controller ECCCNT, and a write/read page buffer WRB (hereinafter, also simply “page buffer WRB”).

For example, the memory bank BK includes a memory cell array MCA that includes a plurality of memory cells MC arranged two-dimensionally in a matrix. The memory cell array MCA can be rephrased as one that includes the memory cells MC in a plurality of memory banks BK. That is, the memory cell array MCA can mean either the entirety of a plurality of memory banks BK or a part of a certain memory bank BK.

Each memory cell MC is connected to a pair of bit lines BL (bit lines BL1 and BL2 shown in FIG. 2, for example) and to one word line WL. That is, one end of each memory cell MC is connected to one bit line BL1 of the paired bit lines BL1 and BL2 and the other end of the memory cell MC is connected to the other bit line BL2 thereof. The paired bit lines BL1 and BL2 extend in a column direction. The word lines WL extend in a row direction orthogonal to the column direction.

The memory bank BK also includes a sense amplifier SA, a write driver WD, a column decoder CD, a row decoder RD, and an error correction code part ECC.

For example, the sense amplifier SA is connected to the memory cells MC via the bit line BL1 and functions to detect data stored in the memory cells MC. At this time, the bit line BL2 is connected to a reference voltage (a ground) via the write driver WD. For example, the write driver WD is connected to the memory cells MC via the bit lines BL1 and BL2 and functions to write data to the memory cells MC. The error correction code part ECC generates the parity based on write data and corrects an error in data read from the memory cell array MCA using the parity.

The command and address decoder CAD receives and decodes commands, addresses, and clocks that determine operations of the memory bank BK. For example, the command and address decoder CAD receives a bank address, a column address, and a row address as the addresses. For example, the command and address decoder CAD receives an active command ACT, a write command WR, a read command RC, and a reset command RST as the commands. The memory bank BK can perform various operations in response to these commands.

The command controller COMC receives the commands indicating the various operations such as a read operation and a write operation (hereinafter, also “data read operation” and “data write operation”) from the SoC 2 and controls the main controller MCNT according to those commands.

The main controller MCNT serving as an internal controller controls the entirety of the memory bank BK to transfer data received from the data buffer DQB to the write driver WD so as to write the data to the memory bank BK according to the addresses or controls the entirety of the memory bank BK to transfer data read from the memory bank BK according to the addresses to the data buffer DQB. In this way, the main controller MCNT performs writing of the data to the memory cell array MCA or reading of the data from the memory cell array MCA.

The column decoder CD is configured to select the paired bit lines BL in a certain column according to the column address. The row decoder RD selects one word line WL according to the row address.

The page buffer WRB temporarily stores the write data input via the input/output part I/O and the data buffer DQB or temporarily stores the read data from the memory cells MC.

The data buffer DQB temporarily holds the read data or the write data so as to output the read data to the SoC 2 via the input/output part I/O or to transfer the write data fetched from the SoC 2 via the input/output part I/O to the inside of the MRAM chip 1.

The input/output part I/O receives the data written to the memory cell array MCA from the SoC 2 or outputs the data read from the memory cell array MCA to the SoC 2.

The mode register MR is a register provided within the MRAM chip 1 so as to hold a state of the MRAM chip 1. For example, the mode register MR holds a flag so as to indicate a read state or a write state. A state of the flag held in the mode register MR indicates whether the MRAM chip 1 performs the write operation or the read operation.

The ECC controller ECCCNT serving as a mode controller is a circuit that determines a memory region to which the error correction code part ECC executes error correction and a memory region to which the error correction code part ECC does not execute the error correction. As for the region to which the error correction code part ECC executes the error correction, the error correction code part ECC generates parity based on the write data and corrects the error in the data read from the memory cell array MCA. On the other hand, as for the memory region to which the error correction code part ECC does not execute the error correction, the error correction code part ECC does not generate the parity at the time of the write operation and does not correct an error at the time of the read operation. The memory region to which the error correction code part ECC executes the error correction or the memory region to which the error correction code part ECC does not execute the error correction can be specified in a page unit that is write or read unit or in a bank BK unit described above.

Although FIG. 2 shows one memory bank BK, a plurality of banks BK are normally arranged two-dimensionally in a matrix.

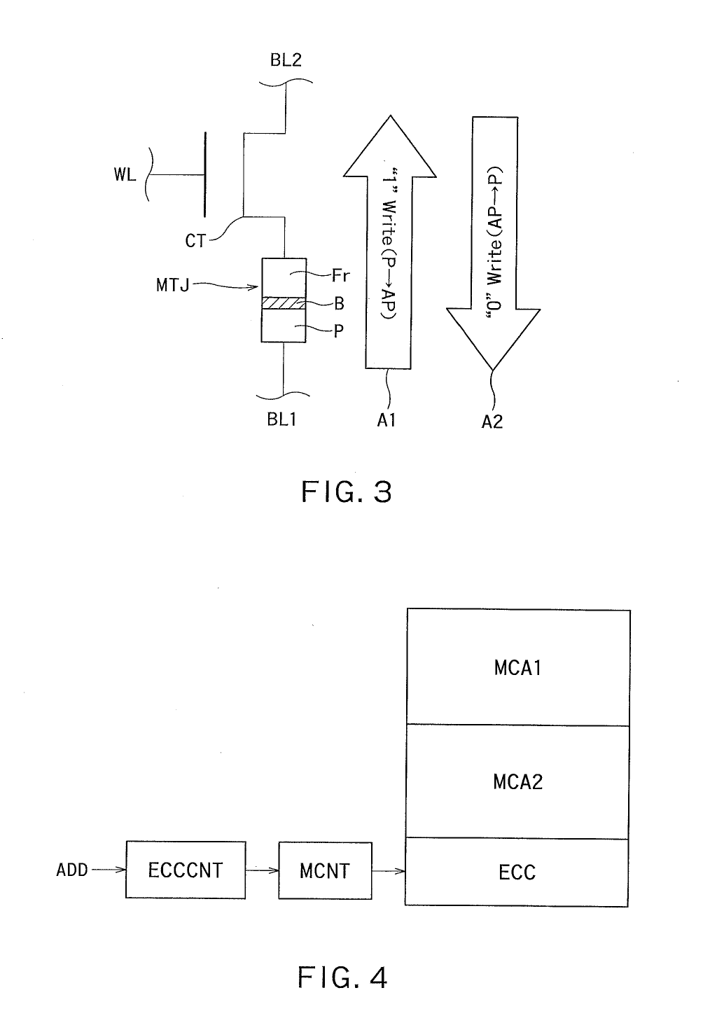

FIG. 3 is an explanatory diagram showing an example of a configuration of the single memory cell MC. Each memory cell MC includes a magnetic tunnel junction (MTJ) element and a cell transistor CT. The MTJ element and the cell transistor CT are connected in series between the bit lines BL1 and BL2. In the memory cell MC, the cell transistor CT is arranged on the side of the bit line BL2 and the MTJ element is arranged on the side of the bit line BL1. A gate of the cell transistor CT is connected to one word line WL.

An STT (Spin Transfer Torque)-MTJ element using a TMR (tunneling magnetoresistive) effect has a stacked structure constituted by two ferromagnetic layers and a nonmagnetic layer (an insulating thin film) sandwiched between the ferromagnetic layers, and stores digital data by a change in a magnetic resistance resulting from spin-polarized tunneling. The MTJ element can be set into either a low resistance state or a high resistance state, depending on magnetization orientations of the two ferromagnetic layers. For example, when it is defined that the low resistance state indicates data “0” and that the high resistance state indicates data “1”, one-bit data can be recorded in the MTJ element. Needless to mention, it can be defined that the low resistance state indicates the data “1” and that the high resistance state indicates the data “0”. For example, the MTJ element is configured so that a pinned layer P, a tunnel barrier layer B, and a recording layer Fr are sequentially stacked as shown in FIG. 3. The pinned layer P and the recording layer Fr are made of a ferromagnetic body whereas the tunnel barrier layer B is made of an insulating film. The pinned layer P is a layer having a fixed magnetization direction, the recording layer Fr is a layer having a variable magnetization direction, and data is recorded in the MTJ element depending on the magnetization direction of the recording layer Fr.

At the time of the write operation, when a current equal to or higher than an inversion threshold current flows in an arrow A1 direction, then the magnetization direction of the recording layer Fr is anti-parallel to that of the pinned layer P, and the MTJ element is set into the high resistance state (the data “1”). At the time of the write operation, when the current equal to or higher than the inversion threshold current flows in an arrow A2 direction, then the magnetization direction of the pinned layer P is parallel to that of the recording layer Fr, and the MTJ element is set into the low resistance state (the data “0”). In this way, different data can be written to the MTJ element, depending on the direction of the current.

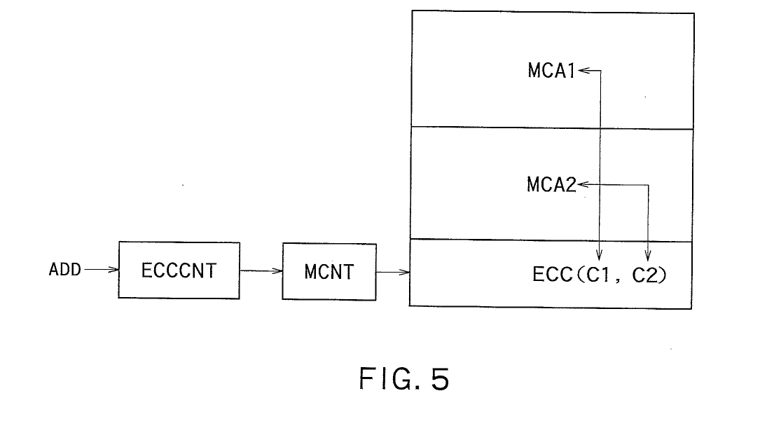

FIG. 4 is a block diagram showing the ECC controller ECCCNT, the main controller MCNT, the error correction code part ECC, and the memory cell array MCA. With reference to FIG. 4, a relation among the ECC controller ECCCNT, the error correction code part ECC, and the memory cell MCA is described in more detail. In the first embodiment, the memory cell array MCA of the MRAM chip 1 includes a first memory region MCA1 and a second memory region MCA2. For example, the first memory region MCA1 functions as the work memory that temporarily stores data in data processing. For example, the second memory region MCA2 functions as the code storage that stores program codes for executing various programs. The first and second memory regions MCA1 and MCA2 can be discriminated in arbitrary units as long as the first and second memory regions MCA1 and MCA2 can be designated by addresses. For example, the first and second memory regions MCA1 and MCA2 can be discriminated in a page unit or bank BK unit.

A higher priority is given to a high write speed and a high read speed (hereinafter, also simply “performance”) for the work memory because the work memory frequently exchanges data for the data processing. On the other hand, a higher priority is given to data reliability (a data retention characteristic, for example) for the code storage because the code storage is used to store the program codes. This is because degradation in the data reliability of the program codes possibly causes a device executing the programs to malfunction or run away. Needless to mention, it is desirable that the work memory has the high data reliability and that the code storage has a high write speed and a high read speed. However, in consideration of respective usage purposes of the work memory and the code storage, the performance is relatively important for the work memory and the data reliability is relatively important for the code storage.

Meanwhile, the error correction code part ECC corrects an error in the read data. The data reliability thereby improves. However, to execute the error correction during the read operation requires a data correction time. Furthermore, to execute the error correction during the write operation requires a parity generation time. That is, when the error correction is to be executed, both the read operation and the write operation require time overhead. In this way, an error correction operation often degrades the performance although the data correction operation is effective to improve the data reliability.

Therefore, the ECC controller ECCCNT according to the first embodiment changes the error correction operation performed by the error correction code part ECC between the first memory region MCA1 and the second memory region MCA2. For example, when data is read from the first memory region MCA1 used as the work memory, the ECC controller ECCCNT controls the error correction code part ECC via the main controller MCNT not to execute the error correction to the data read from the first memory region MCA1. With this configuration, it is possible to improve the performance even if the first memory region MCA1 is used as the work memory and data is frequently read/written for the data processing from/to the first memory region MCA1.

On the other hand, when data is read from the second memory region MCA2 used as the code storage, the ECC controller ECCCNT controls the error correction code part ECC via the main controller MCNT to execute the error correction to the data read from the second memory region MCA2. With this configuration, it is possible to ensure the high data reliability because the error correction is executed when the various programs are executed using the second memory region MCA2 as the code storage.

The MRAM chip 1 according to the first embodiment can thereby improve either the performance or the data reliability (the data retention characteristic, for example) dependently on whether an accessed memory region is the memory region MCA1 or MCA2 (dependently on a type or an attribute of the stored data). As a result, the MRAM chip 1 can realize both the high performance and the high data reliability as a whole.

The ECC controller ECCCNT can turn on the error correction code part ECC when the data is read from the second memory region MCA2 and turn off the error correction code part ECC when the data is read from the first memory region MCA1. This can further improve the performance and contribute to saving of power consumption. The “turn on” of the ECC means applying electric power to the ECC or activating the ECC. The “turn off” of the ECC means stopping applying electric power to the ECC or deactivating the ECC. When activating the ECC, the condition of the ECC may be shifted from a standby condition to an active condition. In the standby condition, electric power is applied to the ECC, but the ECC does not function. In the active condition, electric power is applied to the ECC, and the ECC functions.

According to the first embodiment, the error correction code part ECC does not need to generate the parity when the data is written to the first memory region MCA1. That is, when the data is written to the first memory region MCA1 used as the work memory, the ECC controller ECCCNT controls the error correction code part ECC via the main controller MCNT not to generate the parity of the write data. It is thereby possible to further improve the performance. It is also possible to reduce a memory region that stores the parity. The memory region that stores the data can be thereby made larger than those of conventional techniques.

On the other hand, when the data is written to the second memory region MCA2 used as the code storage, the ECC controller ECCCNT controls the error correction code part ECC via the main controller MCNT to generate the parity of the write data. The error correction code part ECC can thereby correct the error in the data when the data is read from the second memory region MCA2.

The ECC controller ECCCNT can turn on the error correction code part ECC when the data is written to the second memory region MCA2 and turn off the error correction code part ECC when the data is written to the first memory region MCA1. This can further improve the performance and contribute to saving of power consumption.

The ECC controller ECCCNT stores the first and second memory regions MCA1 and MCA2 and whether or not the error correction is necessary (whether or not parity generation is necessary) while causing the first and second memory regions MCA1 and MCA2 to correspond to the latter information. For example, it suffices that the ECC controller ECCCNT stores an address (a page address, a bank address or the like) of one of or both of the first and second memory regions MCA1 and MCA2 using a ROM (Read Only Memory) or a fuse. The ECC controller ECCCNT can thereby distinguish whether external access is access to the first memory region MCA1 or access to the second memory region MCA2 by comparing an address input from outside with the address stored in advance. For example, in a case of the access to the first memory region MCA1, the ECC controller ECCCNT lowers a flag indicating whether the error correction is necessary. For example, in a case of the access to the second memory region MCA2, the ECC controller ECCCNT raises the flag indicating whether the error correction is necessary. It is thereby possible for the MRAM chip 1 not to execute the error correction in the case of the access to the first memory region MCA1 and to execute the error correction in the case of the access to the second memory region MCA2.

When the ECC controller ECCCNT includes the ROM or the fuse, an address indicating whether or not the error correction is necessary is stored in the ROM or the fuse at the time of manufacturing the MRAM chip 1. Furthermore, when an E (Electronic) fuse or the like is used, the address indicating whether or not the error correction is necessary can be stored in the E fuse or the like after packaging the MRAM chip 1 and the SoC 2.

Moreover, the ECC controller ECCCNT can store the address indicating whether or not the error correction is necessary in a register (not shown) within the ECC controller ECCCNT or in a part of the memory cell array MCA. In this case, the ECC controller ECCCNT obtains the address indicating whether or not the error correction is necessary from the register or the memory cell array MCA at the time of access to the memory cell array MCA. Furthermore, in this case, areas (or capacities) of the first and second memory regions MCA1 and MCA2 can be set and changed even after packaging because the address indicating whether or not the error correction is necessary (whether or not the parity generation is necessary) can be rewritten.

For example, the ECC controller ECCCNT raises a flag bit (a mode command) indicating whether or not the error correction is necessary and transmits the flag bit to the main controller MCNT in the case of the access to the first memory region MCA1. The ECC controller ECCCNT lowers the flag bit indicating whether or not the error correction is necessary and transmits the flag bit to the main controller MCNT in the case of the access to the second memory region MCA2. The main controller MCNT controls the operation of the error correction code part ECC based on the flag bit. In this way, the ECC controller ECCCNT can determine whether the error correction is necessary dependently on the accessed memory region MCA1 or MCA2.

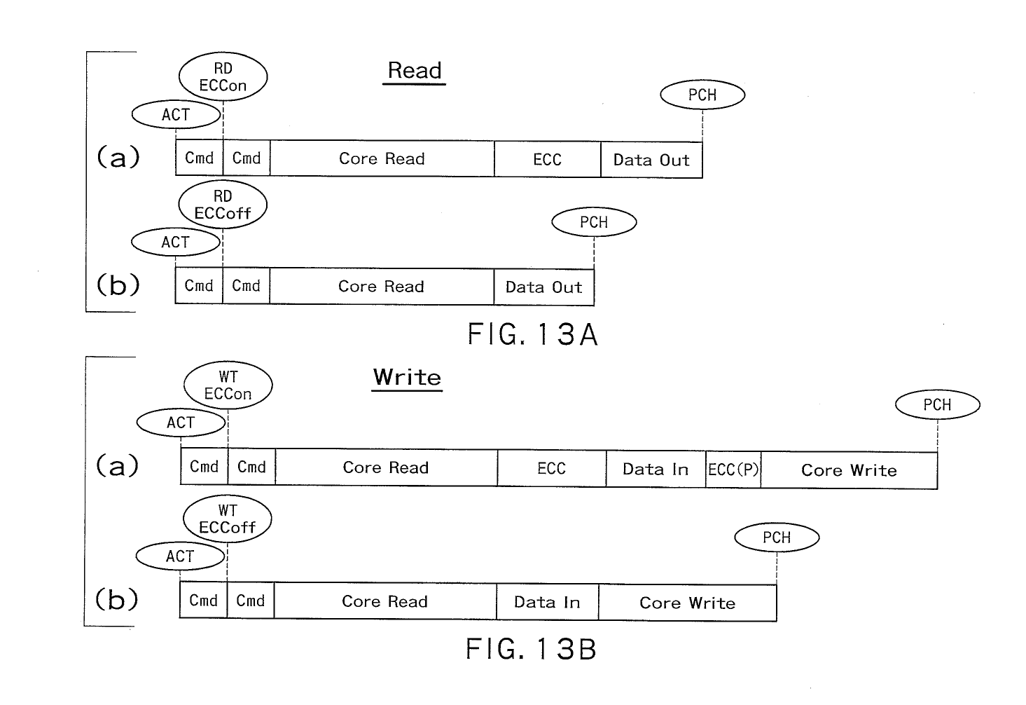

Furthermore, designation of whether to turn on or off the error correction code part ECC can be made to the ECC controller ECCCNT using external commands. For example, FIGS. 12A to 13B are timing charts showing that the designation of the operation of whether to turn on or off the error correction code part ECC is made to the ECC controller ECCCNT in response to the external commands. As shown in FIGS. 12A and 12B, the designation of the operation of whether to turn on or off the error correction code part ECC can be included in the ACT command for activating the memory cell array MCA (a bank, for example). For example, in a case of turning on the error correction code part ECC, an ACT ECCon command is used. In a case of turning off the error correction code part ECC, an ACT ECCoff command is used. When the ACT ECCon command is issued, the internal error correction code part ECC is set into an ON state and operates. As shown in FIG. 12A(a), the error correction code part ECC thereby executes the error correction to the read data. On the other hand, when the ACT ECCoff command is issued, the internal error correction code part ECC is set into an OFF state and does not operate. As shown in FIG. 12A(b), the error correction code part ECC thereby does not execute the error correction to the read data. In FIGS. 12A to 13B, “Cmd” indicates a period of receiving the ACT ECCon command, the ACT ECCoff command, an RD ECCon command, an RD ECCoff command, a WT ECCon command or a WT ECCoff command. “Core Read” indicates a period of the data read operation and “Data Out” indicates a period of an operation for outputting the data to outside of the MRAM chip 1. Furthermore, “RD” indicates that a current operation is the read operation and is a command instructing the data to be output to outside. “PCH” is a command instructing precharge.

To turn on or off the error correction code part ECC can be designated in any of the read operation (Read) and the write operation (Write). For example, as shown in FIG. 12B(a), the error correction code part ECC executes the error correction to the read data in response to the ACT ECCon command in the write operation (Write). Furthermore, the error correction code part ECC generates the parity based on data updated by the write data. On the other hand, as shown in FIG. 12B(b), the error correction code part ECC does not execute the error correction to the read data in response to the ACT ECCoff command and does not generate the parity, either. “ECC (P)” indicates a parity generation period. “Core Write” indicates a period of the data write operation. “WT” indicates that the current operation is the write operation and is a command instructing the write data to be input.

In this way, the error correction code part ECC is turned on or off as needed, so that an operation performed by the MRAM chip 1 can be accelerated.

As shown in FIGS. 13A and 13B, the RD command or the WT command can be used to make the designation of whether to turn on or off the error correction code part ECC. In the timing charts of FIGS. 13A and 13B, the designation of whether to turn on or off the error correction code part ECC is included in the RD command or the WT command. In this way, the ON/OFF designation of the error correction code part ECC is made using the RD ECCon command and the RD ECCoff command in a case of the read operation (Read), and using the WT ECCon command and the WT ECCoff command in a case of the write operation (Write). Even if these external commands are used as described above, effects of the first embodiment are not lost.

As described above, the MRAM chip 1 according to the first embodiment can determine whether or not the error correction is necessary (including whether or not the parity generation is necessary) dependently on the accessed memory region MCA1 or MCA2 (a page or a bank, for example) within the memory cell array MCA during the read operation or the write operation. It is thereby possible to improve the performance by not executing the error correction at the time of the access to the work memory, and to improve the data reliability by executing the error correction at the time of the access to the code storage. Therefore, the first embodiment can realize both the high performance and the high data reliability.

Generally, a DRAM is often used as a work memory and a NAND flash memory is often used as a code storage. However, according to the first embodiment, one MRAM chip 1 is divided into a plurality of memory regions (MCA1 and MCA2) and the MRAM chip 1 determines whether or not the error correction is necessary dependently on the accessed memory region MCA1 or MCA2. Therefore, according to the first embodiment, the memory cell DRAM and the NAND flash memory can be replaced with one MRAM chip 1.

### (Modification of First Embodiment)

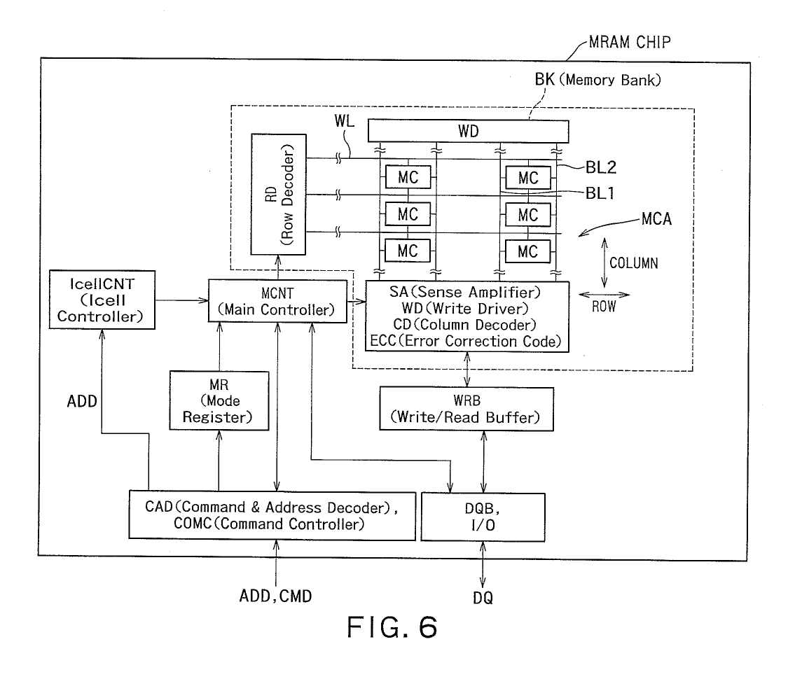

FIG. 5 is a block diagram showing the ECC controller ECCCNT, the main controller MCNT, the error correction code part ECC, and the memory cell array MCA according to a modification of the first embodiment.

The MRAM chip 1 according to the first embodiment determines whether or not the error correction is necessary dependently on the accessed memory region MCA1 or MCA2. In contrast, the MRAM chip 1 according to the present modification changes an error correction capability dependently on the accessed memory region MCA1 or MCA2. The error correction capability is the number of error-correctable bits of data. Therefore, when the error correction capability is high, the reliability of the read data becomes high but the error correction time and the parity generation time become long. On the other hand, when the error correction capability is low, the reliability of the read data becomes relatively low but the error correction time and the parity generation time become short. That is, when the error correction capability is high, the data reliability improves but the performance degrades. When the error correction capability is low, the performance improves but the data reliability degrades.

For example, in a case of reading data from the first memory region MCA1 serving as the work memory, the ECC controller ECCCNT controls the error correction code part ECC to execute the error correction to the data read from the first memory region MCA1 using a first error correction capability C1. On the other hand, in a case of reading data from the second memory region MCA2 serving as the code storage, the ECC controller ECCCNT controls the error correction code part ECC to execute the error correction to the data read from the second memory region MCA2 using a second error correction capability C2 higher than the first error correction capability C1. With this configuration, the present modification can realize both the high performance and the high data reliability similarly to the first embodiment.

### Second Embodiment

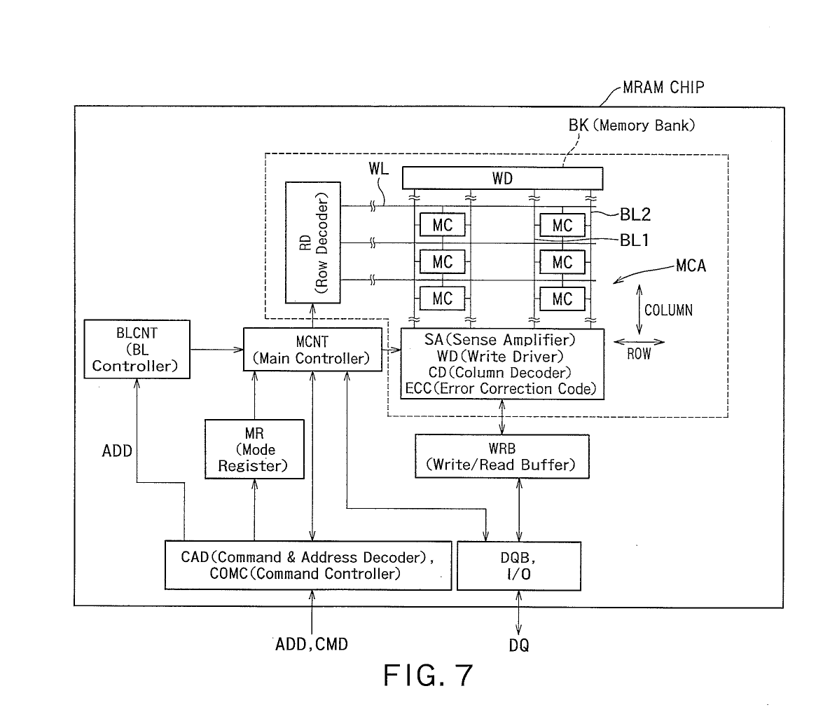

FIG. 6 is a block diagram showing an example of a configuration of the MRAM chip 1 according to a second embodiment. The MRAM chip 1 according to the second embodiment includes a cell current controller IcellCNT in place of the ECC controller ECCCNT. Other configurations of the second embodiment can be identical to corresponding ones of the first embodiment.

In the second embodiment, the cell current controller IcellCNT serving as the mode controller changes a cell current Icell applied to the memory cells MC dependently on the accessed memory region MCA1 or MCA2 (a page or a bank, for example) within the memory cell array MCA during the read operation. For example, in the case of reading data from the first memory region MCA1, the cell current controller IcellCNT instructs the main controller MCNT to apply a first current to the memory cell MC of the first memory region MCA1 as the cell current Icell. In the case of reading data from the second memory region MCA2, the cell current controller IcellCNT instructs the main controller MCNT to apply a second current lower than the first current to the second memory region MCA2 as the cell current Icell.

In a case of an STT-MRAM, data is written or data is read by applying the cell current Icell to the MTJ element at the time of reading the data. When the cell current Icell is high at the time of the read operation, data is possibly written to the memory cell MC. Therefore, the cell current Icell in the read operation is normally set lower than the cell current Icell in the write operation. That is, it is required that the first and second currents be lower than the cell current Icell in the write operation although the first and second currents differ from each other. On the other hand, when the cell current Icell is set to be low, the data sense time becomes long. Therefore, it is preferable to set the cell current Icell to be low so as to maintain the data reliability in the read operation. However, it is preferable to set the cell current Icell to be high so as to improve the performance.

Therefore, in the second embodiment, the cell controller IcellCNT instructs the main controller MCNT to apply a relatively high first current as the cell current Icell in the case of reading data from the work memory (the first memory region MCA1) for which a higher priority is given to the performance. The sense amplifier SA thereby applies the first current to the memory cells MC in the first memory region MCA1. On the other hand, the cell controller IcellCNT instructs the main controller MCNT to apply the second current lower than the first current as the cell current Icell in the case of reading data from the code storage (the second memory region MCA2) for which a higher priority is given to the data reliability such as the data retention characteristics. The sense amplifier SA thereby applies the second current to the memory cells MC in the second memory region MCA2. For example, when a page selected during the data read operation is included in the first memory region MCA1, a voltage difference between the paired bit lines BL1 and BL2 is made relatively large so as to apply the first current to the memory cells MC. On the other hand, when the selected page is included in the second memory region MCA2, the voltage difference between the paired bit lines BL1 and BL2 is made relatively small so as to apply the second current to the memory cells MC. This can differentiate the cell currents Icell applied to the first and second memory regions MCA1 and MCA2 from each other.

Even if the cell current Icell is changed dependently on the accessed memory region MCA1 or MCA2 as described above, the MRAM chip 1 can realize both the high performance and the high data reliability. Therefore, the second embodiment can achieve effects identical to those of the first embodiment.

In the first embodiment, the error correction code part ECC is controlled to operate differently, depending on the accessed memory region MCA1 or MCA2. In the second embodiment, the different cell currents Icell are applied, depending on the accessed memory region MCA1 or MCA2. Therefore, in the first and second embodiments, actual operations performed by the mode controllers differ from each other dependently on the accessed memory region MCA1 or MCA2. Nevertheless, it suffices that the cell current controller IcellCNT can distinguish the first and second memory regions MCA1 and MCA2 from each other and output different commands to the main controller MCNT dependently on the accessed memory region MCA1 or MCA2. Therefore, the configuration of the cell current controller IcellCNT can be identical to that of the ECC controller ECCCNT according to the first embodiment. The second embodiment can be combined with the first embodiment. That is, the MRAM chip 1 can include both the ECC controller ECCCNT and the cell current controller IcellCNT.

### Third Embodiment

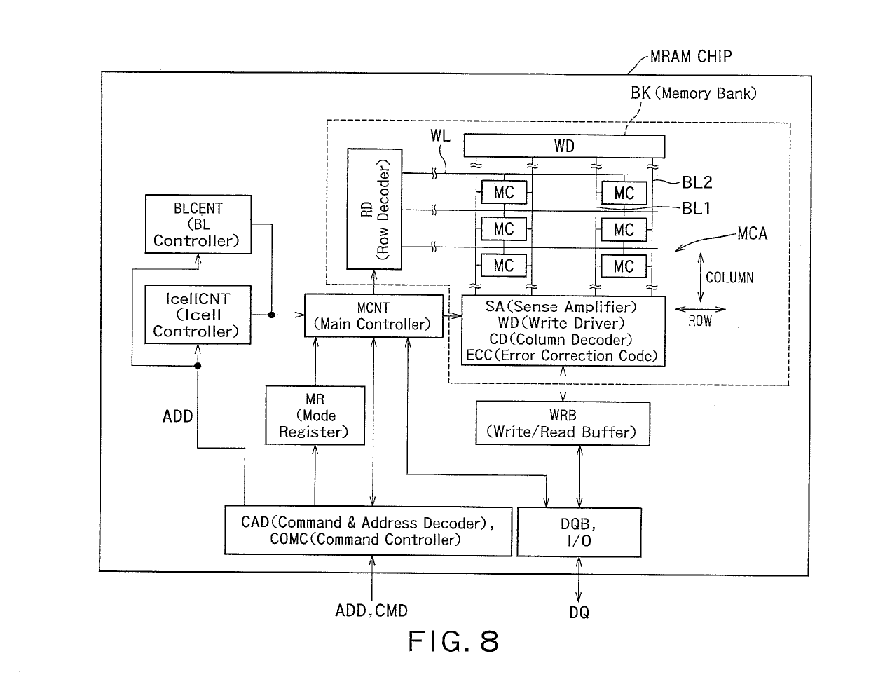

FIG. 7 is a block diagram showing an example of a configuration of the MRAM chip 1 according to a third embodiment. The MRAM chip 1 according to the third embodiment includes a BL voltage controller BLCNT in place of the ECC controller ECCCNT. Other configurations of the third embodiment can be identical to corresponding ones of the first embodiment.

In the third embodiment, the BL voltage controller BLCNT serving as the mode controller changes a voltage (a bit line voltage) applied to the bit lines BL dependently on the accessed memory region MCA1 or MCA2 (a page or a bank, for example) within the memory cell MCA during the read operation. For example, in the case of reading data from the first memory region MCA1, the BL voltage controller BLCNT instructs the main controller MCNT to apply a first bit line voltage (hereinafter, simply “first voltage”) to the bit lines BL in the first memory region MCA1. In the case of reading data from the second memory region MCA2, the BL voltage controller BLCNT instructs the main controller MCNT to apply a second bit line voltage (hereinafter, simply “second voltage”) higher than the first voltage to the bit lines BL in the second memory region MCA2.

Generally, when the bit line voltage is high, a rewritable count decreases (the endurance characteristic degrades) during the read operation or the write operation. Therefore, it is possible to suppress a decrease in the writable count by setting the bit line voltage to be low for the work memory having a high rewrite frequency. On the other hand, the bit line voltage can be set to be relatively high for the code storage having a low rewrite frequency. By raising the bit line voltage, the data reliability improves.

Therefore, in the third embodiment, in the case of reading data from the work memory (the first memory region MCA1) for which a higher priority is given to the rewritable count, the BL voltage controller BLCNT instructs the main controller MCNT to apply the relatively low first voltage. The sense amplifier SA thereby applies the first voltage to the bit lines BL in the first memory region MCA1. On the other hand, in the case of reading data from the code storage (the second memory region MCA2) for which a higher priority is given to the data reliability such as the data retention characteristic, the BL voltage controller BLCNT instructs the main controller MCNT to apply the second voltage higher than the first voltage. The sense amplifier SA thereby applies the second voltage to the bit lines BL in the second memory region MCA2.

In this way, by changing the bit line voltage dependently on the accessed region MCA1 or MCA2, the MRAM chip 1 can realize both the high memory rewritable count (the endurance characteristic) and the high data reliability such as the high data retention characteristic.

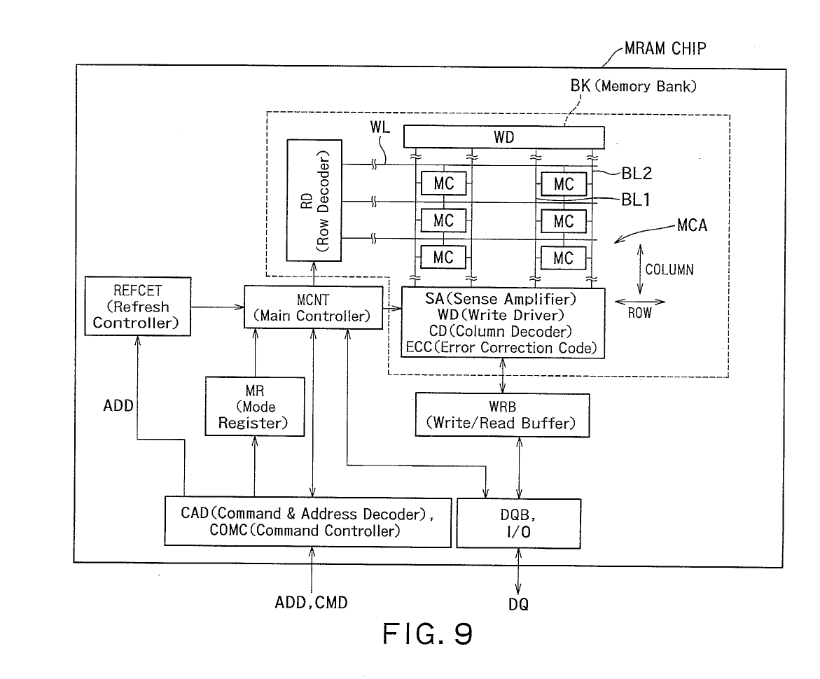

In the first embodiment, the error correction code part ECC is controlled to operate differently, depending on the accessed memory region MCA1 or MCA2. In the third embodiment, the different bit line voltages are applied, depending on the accessed memory region MCA1 or MCA2. Therefore, in the first and third embodiments, actual operations performed by the mode controllers differ from each other dependently on the accessed memory region MCA1 or MCA2. Nevertheless, it suffices that the BL voltage controller BLCNT can distinguish the first and second memory regions MCA1 and MCA2 from each other and output different commands to the main controller MCNT dependently on the accessed memory region MCA1 or MCA2. Therefore, the configuration of the BL voltage controller BLCNT can be identical to that of the ECC controller ECCCNT according to the first embodiment. The third embodiment can be combined with the first embodiment and/or the second embodiment. That is, the MRAM chip 1 can include two of or all of the BL voltage controller BLCNT, the ECC controller ECCCNT, and the cell current controller IcellCNT. For example, FIG. 8 is a block diagram showing an example of a configuration of the MRAM chip 1 according to a combination of the third embodiment with the second embodiment. In this way, the third embodiment can realize both the high memory rewritable count and the high data reliability more satisfactorily by being combined with the second embodiment.

### Fourth Embodiment

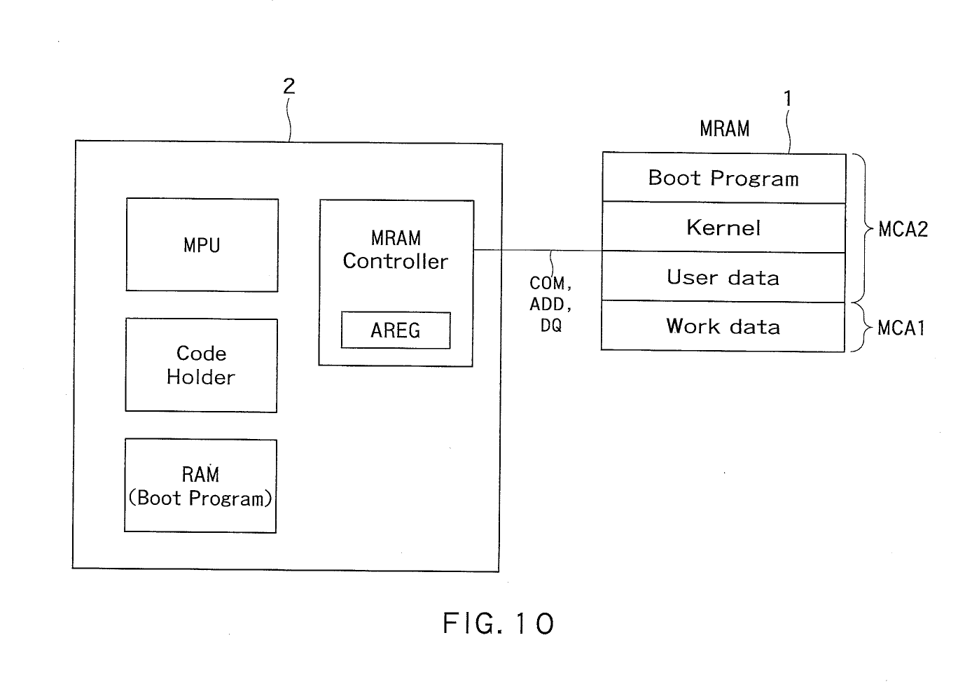

FIG. 9 is a block diagram showing an example of a configuration of the MRAM chip 1 according to a fourth embodiment. The MRAM chip 1 according to the fourth embodiment includes a refresh controller REFCNT in place of the ECC controller ECCCNT. Other configurations of the fourth embodiment can be identical to corresponding ones of the first embodiment.

In the fourth embodiment, the refresh controller REFCNT serving as the mode controller changes a refresh-operation execution frequency dependently on the accessed memory region MCA1 or MCA2 (a page or a bank, for example) within the memory cell array MCA. A refresh operation is an operation for temporarily reading the data stored in the memory cell MC to the page buffer WRB and for writing back the data to the same memory cell MC.

For example, the refresh controller REFCNT instructs the main controller MCNT to perform the refresh operation to the first memory region MCA1 with a first frequency (a first cycle). Furthermore, the refresh controller REFCNT instructs the main controller MCNT to perform the refresh operation to the second memory region MCA2 with a second frequency (a second cycle).

Generally, the refresh operation contributes to improving the data reliability such as the data retention characteristic. However, during a period of the refresh operation, the access to the memory cell array MCA is prohibited. For this reason, when an interval (a cycle) between a certain refresh operation and a next refresh operation is short and the refresh-operation execution frequency is high, the performance possibly degrades. Therefore, it is preferable that the refresh-operation execution frequency is high so as to improve the data reliability. On the other hand, it is preferable that the refresh-operation execution frequency is low so as to improve the performance. The frequency is the number of times of the refresh operation executed within a predetermined period.

Therefore, in the fourth embodiment, in a case of performing the refresh operation to the work memory (the first memory region MCA1) for which a higher priority is given to the performance, the refresh controller REFCNT instructs the main controller MCNT to perform the refresh operation to the first memory region MCA1 with the relatively low first frequency. An accessible period to the work memory is thereby made long, so that the performance can improve. On the other hand, in a case of performing the refresh operation to the code storage (the second memory region MCA2) for which a higher priority is given to the data reliability such as the data retention characteristic, the refresh controller REFCNT instructs the main controller MCNT to perform the refresh operation to the second memory region MCA2 with the second frequency higher than the first frequency. The data reliability of the code storage can thereby improve.

In this way, the MRAM chip 1 according to the fourth embodiment can realize both the high performance and the high reliability by changing the refresh-operation execution frequency dependently on the accessed memory region MCA1 or MCA2. Therefore, the fourth embodiment can achieve effects identical to those of the first embodiment.

In the first and fourth embodiments, actual operations performed by the mode controllers differ from each other dependently on the accessed memory region MCA1 or MCA2. Nevertheless, it suffices that the refresh controller REFCNT can distinguish the first and second memory regions MCA1 and MCA2 from each other and output different commands to the main controller MCNT dependently on the accessed memory region MCA1 or MCA2. Therefore, the configuration of the refresh controller REFCNT can be identical to that of the ECC controller ECCCNT according to the first embodiment.

According to the first to fourth embodiments described above, the mode controllers (ECCCNT, IcellCNT, BLCNT, and REFCNT) change operation modes between the first memory region MCA1 and the second memory region MCA2. The MRAM chip 1 according to each of the first to fourth embodiments can thereby realize both the high data reliability and the high performance or realize both the high data reliability and the high endurance characteristic.

Two or more of the first to fourth embodiments can be combined. It is thereby possible to further improve the data reliability and the performance and/or further improve the data reliability and the endurance characteristic.

### Fifth Embodiment

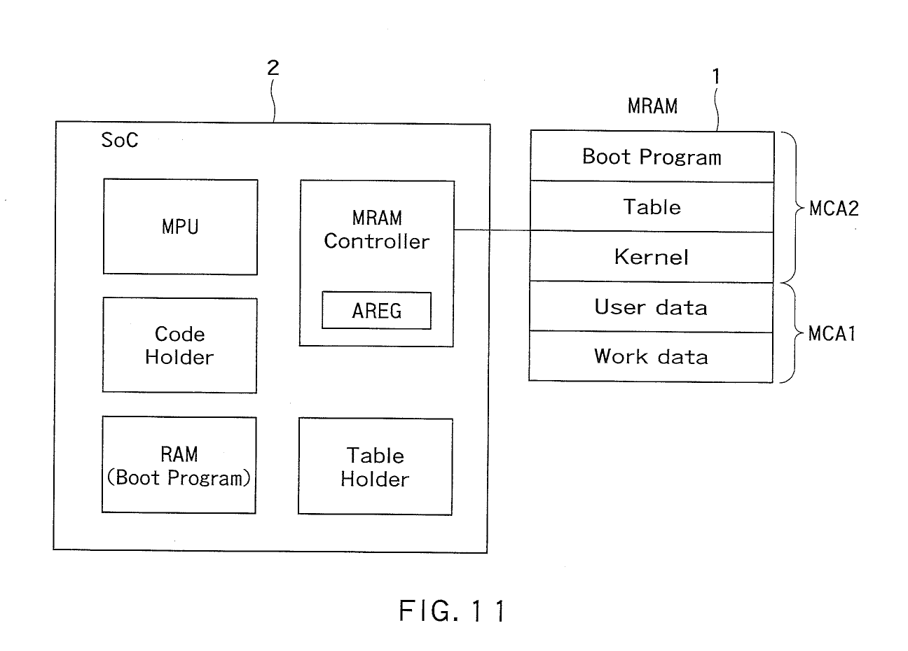

FIG. 10 is a block diagram showing an example of a configuration of a system (a memory system) according to a fifth embodiment. This system includes the MRAM chip 1 and the SoC 2. As the MRAM chip 1, the same MRAM chip 1 as one of those according to the first to fourth embodiments can be used. The first memory region MCA1 serving as the work memory of the MRAM chip 1 stores work data. The second memory region MCA2 serving as the code storage stores a boot program for booting an operating system (OS) at the time of powering on the system, a kernel serving as the OS, and user data.

The SoC 2 includes an MPU, an MRAM controller, an initialization code holder (hereinafter, also “code holder”), and a RAM. The MPU is a microprocessor of the SoC 2. The MRAM controller transmits various commands such as a read command, a write command, and a mode command to the MRAM chip 1. The MRAM controller includes an area register AREG that stores different mode commands for the first memory region MCA1 and the second memory region MCA2, respectively. The mode commands are commands output to the MRAM chip 1 so as to change operation modes between the first memory region MCA1 and the second memory region MCA2. It suffices that the mode commands are bit data indicating the operation modes, respectively.

The initialization code holder holds an initialization code used first after powering on the system. The initialization code initializes the SoC 2 and establishes connection of the SoC 2 to the MRAM chip 1.

For example, the RAM fetches in and stores the boot program of the MRAM chip 1 during an initialization operation after powering on the system. The performance can improve by storing the boot program in the RAM of the SoC 2.

Generally, in a case of using a DRAM as a work memory and using a NAND flash memory as a code storage, the DRAM is unable to hold data when the system is powered off because the DRAM is a volatile memory. Therefore, the DRAM needs to copy necessary data from the NAND flash memory right after the power is turned on. For example, using an initialization code of an SoC, a boot program within the NAND flash memory is read to a RAM within the SoC. A boot loader within the NAND flash memory is copied to the DRAM in response to this boot program and the kernel within the NAND flash memory is then copied to the DRAM by the boot loader. Start-up of a memory system is thus completed.

In contrast, according to the fifth embodiment, the MRAM chip 1 that is a nonvolatile memory includes not only the code storage (the second memory region MCA2) but also the work memory (the first memory region MCA1), and collectively stores the boot program, the kernel, the user data, and the work data. Therefore, even if the memory system is powered off, the data stored in the MRAM chip 1 is effectively held. At the time of powering on the system, the data stored in the MRAM chip 1 can be effectively used without copying the boot program, the kernel, the user data, and the work data. Therefore, in the system according to the fifth embodiment, it suffices to initialize the SoC 2 using the boot program so as to establish the connection between the MRAM chip 1 and the SoC 2 right after the system is powered on. As a result, the memory system start-up time can be reduced.

The area register AREG stores the mode commands, and the MRAM controller transmits the mode command corresponding to the memory region MCA1 or MCA2 that is accessed during the read operation or the write operation to the MRAM chip 1. An operation performed by the MRAM chip 1 that receives the mode command can be considered to be the same as one of those according to the first to fourth embodiments. With this configuration, the memory system according to the fifth embodiment can achieve effects identical to those of the first to fourth embodiments.

A read time or a write time of the work memory (the first memory region MCA1) is shorter than that of the code storage (the second memory region MCA2). Therefore, the SoC 2 changes the timing of outputting a next operation command dependently on the accessed memory region MCA1 or MCA2. For example, in the case of the access to the first memory region MCA1, the SoC 2 outputs the next operation command to the MRAM chip 1 after a first interval that is relatively short from the access. On the other hand, in the case of the access to the second memory region MCA2, the SoC 2 outputs the next operation command to the MRAM chip 1 after a second interval longer than the first interval from the access. The first and second intervals can be determined by the mode commands output from the SoC 2 to the MRAM chip 1.

The boot program can be included in the initialization code held in the initialization code holder. In this case, the SoC 2 can obtain the boot program from the initialization code holder at the time of powering on the system. Therefore, it is not always necessary to store the boot program in the MRAM chip 1.

In the fifth embodiment, settings of a write protect (a write mask) can be changed dependently on the accessed memory region MCA1 or MCA2. That is, the write protect can be used as the mode command. The write protect is a command for instructing the write data in a page unit or the like whether to be actually written. The write protect is stored in the MRAM controller of the SoC 2 and the write protect as well as the write command and the data is transmitted to the MRAM chip 1.

In a case of a protect state where the write protect is set to the memory region MCA1 or MCA2, the data in the memory region MCA1 or MCA2 is prohibited from being rewritten and data is not written to the memory region MCA1 or MCA2. On the other hand, in a case of an unprotect state where the write protect is not set to the memory region MCA1 or MCA2, the data in the memory region MCA1 or MCA2 can be rewritten and data can be written to the memory region MCA1 or MCA2.

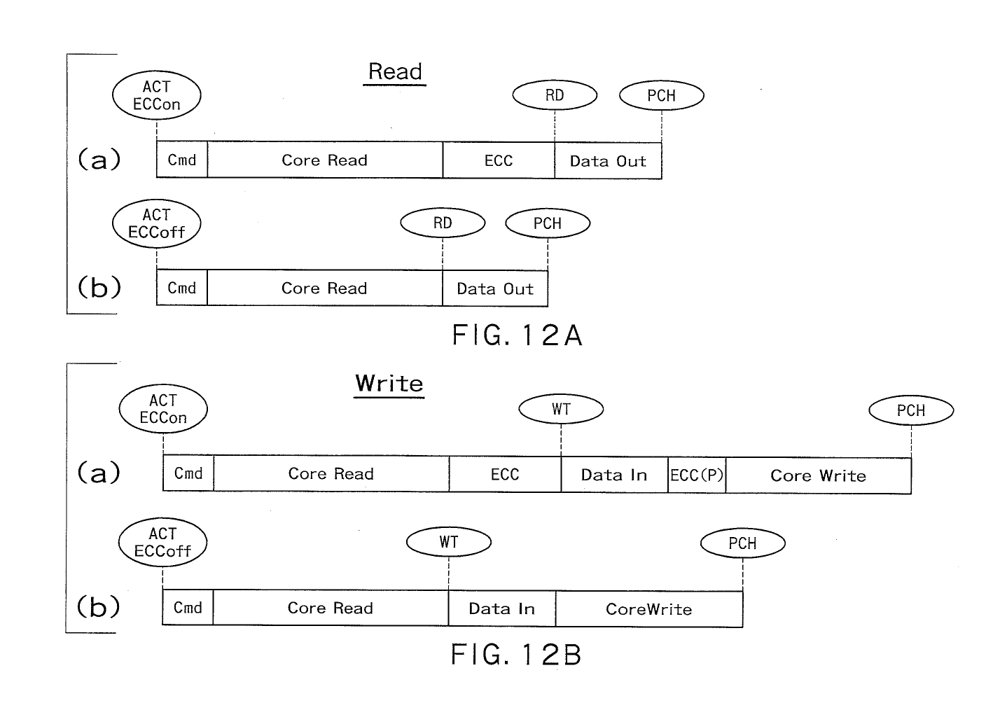

For example, the first memory region MCA1 serving as the work memory is set into the unprotect state, and the second memory region MCA2 serving as the code storage is set into the protect state. This can prevent the boot program and the data relating to the OS such as the kernel from being erroneously erased. On the other hand, the data relating to the work memory can be updated. In this case, as shown in FIG. 11, the user data can be included in the first memory region MCA1 serving as the work memory. It is thereby possible to update the user data. The settings of such a write protect can be combined with each of the first to fourth embodiments.

### (Setting 1 of Mode Commands and Memory Regions)

A correspondence between the mode commands and the memory regions (MCA1 and MCA2) can be set into the area register AREG at the time of manufacturing the SoC 2. The area register AREG can be formed using the ROM or the fuse similarly to the mode controllers according to the first to fourth embodiments. It suffices to store addresses of the memory regions (MCA1 and MCA2) corresponding to the respective mode commands in the area register AREG similarly to the ECC controller ECCCNT according to the first embodiment. The SoC 2 can thereby output the mode command corresponding to the accessed memory region MCA1 or MCA2 to the MRAM chip 1.

### (Setting 2 of Mode Commands and Memory Regions)

The correspondence between the mode commands and the memory regions (MCA1 and MCA2) can be stored in the code holder by being included in the initialization code at the time of manufacturing the SoC 2. In this case, during the initialization operation after the system is powered on, when the initialization code is processed, the correspondence between the mode commands and the memory regions (MCA1 and MCA2) is set into the area register AREG of the MRAM controller. The SoC 2 can thereby output the mode command corresponding to the accessed memory region MCA1 or MCA2 to the MRAM chip 1.

### (Setting 3 of Mode Commands and Memory Regions)

The correspondence between the mode commands and the memory regions (MCA1 and MCA2) can be specified in the boot program stored in the MRAM chip 1.

In this case, during the initialization operation after the system is powered on, the SoC 2 obtains the boot program from the MRAM chip 1 and copies the boot program to the RAM within the SoC 2. Next, the MPU executes the boot program, thereby setting the correspondence between the mode commands and the memory regions (MCA1 and MCA2) into the area register AREG. The SoC 2 can thereby output the mode command corresponding to the accessed memory region MCA1 or MCA2 to the MRAM chip 1.

In a case of specifying the correspondence between the mode commands and the memory regions (MCA1 and MCA2) in the boot program, the correspondence between the mode commands and the memory regions (MCA1 and MCA2) can be changed in response to a request from the OS (the kernel). For example, when a capacity of the OS increases due to version upgrade of the OS, a part of the memory region specified as the first memory region MCA1 is changed to the second memory region MCA2 so as to expand the code storage. In this case, after changing the correspondence between the mode commands and the memory regions (MCA1 and MCA2) specified in the boot program within the MRAM chip 1, the changed boot program is copied to the RAM and is executed. The correspondence between the mode commands and the memory regions (MCA1 and MCA2) set into the area register AREG is thereby updated. The SoC 2 can thereby output the mode command corresponding to the changed memory region MCA1 or MCA2 to the MRAM chip 1.

### (Setting 4 of Mode Commands and Memory Regions)

FIG. 11 is a block diagram showing an example of a configuration of a memory system according to the modification of the fifth embodiment. The SoC 2 in the memory system according to the modification further includes a table holder. The table holder stores a logical-address/physical-address conversion table (hereinafter, simply “address conversion table”). The address conversion table is a table in which a correspondence between physical addresses and logical addresses is set in a page unit. The correspondence between the mode commands and the memory regions (MCA1 and MCA2) can be specified in the address conversion table. That is, the address conversion table includes not only the correspondence between the physical addresses and the logical addresses but also the mode commands. For example, the address conversion table records the physical addresses, the logical addresses, and the mode commands in a page unit or a bank BK unit while causing the physical addresses, the logical addresses, and the mode commands to correspond to one another.

In the case of the access to the MRAM chip 1 during the read operation or the write operation, the SoC 2 transmits the mode command corresponding to the accessed memory region MCA1 or MCA2 from the table holder to the MRAM chip 1 via the MRAM controller. The operation mode can be thereby changed in a page unit or a bank BK unit. An operation performed by the MRAM chip 1 that receives the mode command can be identical to any one of those according to the first to fourth embodiments.

At the time of exiting and powering off the system, the SoC 2 transmits the address conversion table to the MRAM chip 1 and the address conversion table is stored in the MRAM chip 1.

On the other hand, during the initialization operation after the system is powered on, the SoC 2 obtains the boot program from the MRAM chip 1 and copies the boot program to the RAM within the SoC 2. Next, the MPU executes the boot program, thereby copying the address conversion table within the MRAM chip 1 to the table holder. The SoC 2 can thereby output the mode command corresponding to the accessed memory region MCA1 or MCA2 to the MRAM chip 1.

In the case of specifying the correspondence between the mode commands and the memory regions (MCA1 and MCA2) in the address conversion table, the correspondence between the mode commands and the memory regions (MCA1 and MCA2) can be changed in response to a request from the OS (the kernel). For example, when the capacity of the OS increases due to the version upgrade of the OS, a part of the memory region specified as the first memory region MCA1 is changed to the second memory region MCA2 so as to expand the code storage. In this case, the SoC 2 changes the correspondence between the mode commands and the memory regions (MCA1 and MCA2) specified in the address conversion table held in the table holder. The SoC 2 can thereby output the mode command corresponding to the changed memory region to the MRAM chip 1.

The settings of the correspondence between the mode commands and the memory regions (MCA1 and MCA2) are not limited to the examples of the settings described above and other setting methods can be used. With these settings, the memory system according to the fifth embodiment can operate similarly to the first to fourth embodiments and can achieve effects identical to those of the first to fourth embodiments. Furthermore, in the settings 3 and 4, the settings of the correspondence between the mode commands and the memory regions (MCA1 and MCA2) can be changed in response to the request from the OS (the kernel). The memory system can thereby dynamically change the memory region MCA1 serving as the work memory and the memory region MCA2 serving as the code storage.

A memory cell array formation may be disclosed in U.S. patent application Ser. No. 12/407,403 filed on Mar. 19, 2009. U.S. patent application Ser. No. 12/407,403, the entire contents of which are incorporated by reference herein.

Furthermore, a memory cell array formation may be disclosed in U.S. patent application Ser. No. 12/406,524 filed on Mar. 18, 2009. U.S. patent application Ser. No. 12/406,524, the entire contents of which are incorporated by reference herein.

Furthermore, a memory cell array formation may be disclosed in U.S. patent application Ser. No. 12/679,991 filed on Mar. 25, 2010. U.S. patent application Ser. No. 12/679,991, the entire contents of which are incorporated by reference herein.

Furthermore, a memory cell array formation may be disclosed in U.S. patent application Ser. No. 12/532,030 filed on Mar. 23, 2009. U.S. patent application Ser. No. 12/532,030, the entire contents of which are incorporated by reference herein.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor storage device comprising:
a memory cell array comprising a plurality of memory cells, the memory cell array including a first region and a second region;
an internal controller configured to perform writing of data to the memory cells or reading of data from the memory cells;
an input/output part configured to receive the data written to the memory cells or to output the data read from the memory cells; and
a mode controller configured to operate a first region in a first mode and a second region in a second mode.

2. The device of claim 1, further comprising an error correction part configured to correct an error in the data read from the memory cells, wherein
the first and second modes are operation modes of error correction operations performed by the error correction part, and
the mode controller is configured to change an error correction operation between the first mode and the second mode.

3. The device of claim 2, wherein
the mode controller is configured to control the error correction part not to execute error correction to the data read from the first memory region, and
the mode controller is configured to control the error correction part to execute the error correction to the data read from the second memory region.

4. The device of claim 3, wherein
the mode controller is configured to turn off the error correction part in a case of reading the data from the first memory region, and
the mode controller is configured to turn on the error correction part in a case of reading the data from the second memory region.

5. The device of claim 2, wherein
the mode controller is configured to control the error correction part to execute error correction to the data read from the first memory region by using a first error correction capability, and
the mode controller is configured to control the error correction part to execute the error correction to the data read from the second memory region by using a second error correction capability, the second error correction capability being higher than the first error correction capability.

6. The device of claim 1, wherein
the mode controller is configured to instruct the internal controller to apply a first current to the memory cells in the first memory region, and
the mode controller is configured to instruct the internal controller to apply a second current lower than the first current to the memory cells in the second memory region.

7. The device of claim 1, wherein
the mode controller is configured to instruct the internal controller to apply a first voltage to a bit line in the first memory region, and
the mode controller is configured to instruct the internal controller to apply a second voltage higher than the first voltage to a bit line in the second memory region.

8. The device of claim 1, wherein
the mode controller is configured to instruct the internal controller to perform a refresh operation to the first memory region with a first frequency, the refresh operation being an operation for temporarily reading the data from the memory cells and for writing back the data to the memory cells, and
the mode controller is configured to instruct the internal controller to perform the refresh operation to the second memory region with a second frequency higher than the first frequency.

9. The device of claim 1, wherein the mode controller is configured to store an address of the first memory region or the second memory region in a ROM or a fuse.

10. A semiconductor storage device comprising:
a memory cell array comprising a plurality of memory cells, the memory cell array including a first region and a second region;
an internal controller configured to perform writing of data to the memory cells or reading of data from the memory cells;
an input/output part configured to receive the data written to the memory cells or to output the data read from the memory cells, wherein
the input/output part is configured to receive mode commands for operating a first region in a first mode and a second region in a second mode, and
the internal controller is configured to respectively operate a first region in a first mode and a second region in a second mode according to the mode commands.

11. A memory system comprising:
a semiconductor storage device comprising: a memory cell array comprising a first memory region and a second memory region; an internal controller configured to perform writing of data to the memory cell array or reading of data from the memory cell array, and configured to operate a first region in a first mode and a second region in a second mode; and an input/output part configured to receive the data to be written to the memory cell array or to output the data read from the memory cell array; and
an SoC configured to store mode commands for changing the operation mode between the first mode and the second mode, and configured to output the mode command corresponding to an accessed memory region, the accessed memory region being either the first memory region or the second memory region.

12. The system of claim 11, wherein
the SoC instructs the internal controller to prohibit the data in the first memory region from being overwritten in a case of writing the data to the first memory region, and
the SoC instructs the internal controller to permit the data in the second memory region to be overwritten in a case of writing the data to the second memory region.

13. The system of claim 11, wherein correspondences between the first and second memory regions and the mode commands are stored in the memory cell array and copied into the SoC after powering on the memory system.

14. The memory system of claim 13, wherein the correspondences between the first and second memory regions and the mode commands are specified in an address conversion table showing correspondences between physical addresses and logical addresses of the memory cell array.

15. The memory system of claim 13, wherein the correspondences between the first and second memory regions and the mode commands are changeable.

16. The memory system of claim 14, wherein the correspondences between the first and second memory regions and the mode commands are changeable.
